(19) United States
(12) Patent Application Publication
(10) Pub. No.: US 2026/0142098 A1
(43) Pub. Date: May 21, 2026

(54) KEYPAD SWITCH

(71) Applicant: RESIDEO LLC, Golden Valley, MN (US)

(72) Inventors: XiuKuan Yang, Shanghai (CN); Xuemei Wu, Shanghai (CN); Juanchun Peng, Shanghai (CN)

(73) Assignee: RESIDEO LLC, Golden Valley, MN (US)

(21) Appl. No.: 19/121,698

(22) PCT Filed: Oct. 17, 2022
(86) PCT No.: PCT/US2022/046887

§ 371 Date: Apr. 16, 2025

(51) Int. Cl. H01H 13/04; H01H 13/14; H05K 1/181

(52) U.S. Cl. CPC H01H 13/04; H01H 13/14; H05K 1/181; H05K 2201/10053

(57) ABSTRACT

A dome switch comprising a resiliently compressible keycap; an electrically conductive element enclosed by the resiliently compressible keycap; and a switch circuit located under the resiliently compressible keycap and the electrically conductive element, the switch circuit comprising a first circuit board trace and a second circuit board trace, wherein the first circuit board trace and the second circuit board trace are electrically separated; wherein: the first circuit board trace comprises a central portion and a plurality of first projections extending from the central portion to form a non-convex shape; the second circuit board trace comprises a surrounding portion and a plurality of second projections extending from the surrounding portion to form a non-convex shape; wherein the second circuit board trace is arranged to enclose a majority part of the first circuit board trace and the first projections and the second projections are arranged to be positioned in an alternating manner; and wherein the dome switch is configured such that upon being depressed, the resiliently compressible keycap is operable to enable an electrical contact between the electrically conductive element and at least part of the first circuit board trace and at least part of the second circuit board trace so as to temporarily complete the switch circuit.

### TECHNICAL FIELD

The present invention generally relates to keypad switch and in particular dome switch and its applications in safety and/or security systems.

### BACKGROUND

A keypad is a pad of buttons set with an arrangement of digits, symbols, or alphabetical letters. Keypads are used on many electronic devices that require user input. For example, the control panel of a safety and/or security system often comprises a keypad that forms part of a user interface configured to enable interaction between a human user and the safety and/or security system (e.g., for arming or disarming the system).

As one of more important components of a keypad, keypad switches determine the overall performance and lifespan of the keypad. Driven by different applications, various different types of keypad switches have been made available. The existing types of keypad switches include membrane switch, mechanical switch, dome switch, capacitive switch, etc., among which dome switch is the most common type of switch technology in keypads or keyboards, predominately due to their simple structures and low costs. An existing dome switch comprises a dome or keycap, typically made of metal or rubber, and an underlying circuit, typically comprising two electrically separate circuit board traces acting as two electrodes. When a key is pressed, the dome of a dome switch is collapsed which subsequently connects the two circuit traces and completes the underling electrical circuit, thereby resulting in registration of the information associated with the keystroke.

In a typical mechanical switch, a rigid keycap is mountably placed above a mechanical switching mechanism which connects to an underlining electrical circuit. Upon being pressed by a user, the keycap slides down a shaft until the mechanical switching mechanism is actuated, thus resulting in connection of the underlining electrical circuit and registration of the keystroke. The restricted moving direction of the keycap imposes a great limitation in the direction of the pressing force applied by a user on the keycap. Where the pressing direction deviates from the keycap moving direction, the keycap will either not move at all or not travel the required distance and consequently the mechanical switching mechanism will not be actuated. This often occurs when a user tries to press a keycap on one of its edges or side faces rather than on its front face.

In a typical dome switch, a flexible keycap typically made from a soft and resilient material (e.g., rubber) is mountably placed above an underlying electrical circuit. Upon being pressed by a user, the flexible keycap is collapsed to a flat shape. The collapsed keycap acts as an electrical conductor which temporarily connects the associated two circuit board traces and completes the electrical circuit. Subsequently, the flexible keycap self-recovers its default form resulting in electrical separation of the two circuit board traces and thus disconnection of the circuit. The use of flexible keycap allows dome switches to accept a broader angular range of the pressing direction than mechanical switches. However, existing dome switches still cannot be actuated in a reliable and consistent manner when a pressing force is applied on the peripheral region or the side wall of their keycaps.

Capacitive switches remove the need of keycaps and thus can be used as a solution for the aforementioned side-pressing issue. However, capacitive switches are comparatively more complex and more expensive and can cause electromagnetic interference (EMI) issues that are unacceptable for many applications. At present, the prior art lacks a simple, cheap yet reliable solution for the side-pressing issue.

Objects and aspects of the present claimed invention seek to alleviate at least these problems with the prior art.

### SUMMARY

According to a first aspect of the present invention, there is provided a dome switch, comprising a resiliently compressible keycap; at least one electrically conductive element enclosed by the resiliently compressible keycap; and a switch circuit located under the resiliently compressible keycap and the at least one electrically conductive element, the switch circuit comprising a first circuit board trace and a second circuit board trace, wherein the first circuit board trace and the second circuit board trace are electrically separated; wherein: the first circuit board trace comprises a central portion and a plurality of first projections extending from the central portion to form a non-convex shape; the second circuit board trace comprises a surrounding portion and a plurality of second projections extending from the surrounding portion to form a non-convex shape; wherein the second circuit board trace is arranged to enclose a majority part of the first circuit board trace and the first projections and the second projections are arranged to be positioned in an alternating manner; and wherein the dome switch is configured such that upon being depressed, the resiliently compressible keycap is operable to enable an electrical contact between the at least one electrically conductive element and at least part of the first circuit board trace and at least part of the second circuit board trace so as to temporarily complete the switch circuit.

In an embodiment, the central portion of the first circuit board trace comprises an inner ring element and each of the plurality of first projections is separate from others and extends outwardly from the inner ring element, and wherein the surrounding portion comprises an outer ring element and each of the plurality of second projections extends inwardly from the outer ring element and is arranged to be placed in a gap formed between any two immediately adjacent first projections of the plurality of first projections of the first circuit board trace.

In an embodiment, the first circuit board trace comprises at least two base portions, each base portion comprising a central portion and a plurality of first projections extending from the central portion to form a non-convex shape.

In an embodiment, the dome switch is arranged such that the number of the first projections equals to the number of the second projections.

In an embodiment, the first projections of the first circuit board trace and the second projections of the second circuit board trace are arranged to have complementary shapes.

In an embodiment, the first projections and the second projections both have a trapezoid shape. In an embodiment, the resiliently compressible keycap comprises a base and a side wall extending from the peripheral of the base to the underling switch circuit.

In an embodiment, the base of the resiliently compressible keycap comprises a flat top face on which a pressing force is applicable.

In an embodiment, the base of the resiliently compressible keycap comprises a curved top face on which a pressing force is applicable.

In an embodiment, the base and the side wall of the keycap are arranged to provide an internal surface defining a cavity for enclosing the at least one electrically conductive element.

In an embodiment, the keycap is arranged such that the at least one electrically conductive element is affixed to the internal surface of the base and/or the side wall of the keycap.

In an embodiment, each of the at least one electrically conductive element is made from carbon or a metal.

In an embodiment, each of the at least one electrically conductive element is in the form of a ring structure.

In an embodiment, each of the at least one electrically conductive element is in the form of a disk structure.

In an embodiment, the dome switch is arranged such that the electrode arrangement is fully enclosable by the side wall of the keycap and the at least one electrically conductive element is fully within a boundary of the electrode arrangement.

Other aspects of the invention comprise a keypad comprising an array of dome switches according to the embodiments of the first aspect.

### BRIEF DESCRIPTION OF THE DRAWINGS

Embodiments of the present invention will now be described by way of example only and with reference to the accompanying drawings, in which:

FIG. 1 shows a front view of an example keypad that forms an integral part on a control panel of a security system;

FIG. 2 shows part of a circuit diagram of an example keypad (e.g., as shown in FIG. 1); and

FIG. 3A shows a perspective view of a keycap assembly of a dome switch according to a first embodiment;

FIG. 3B shows a perspective view of the internal arrangement of the keycap (e.g., as shown in FIG. 3A) according to the first embodiment;

FIG. 4A shows a front view of an electrode arrangement of the dome switch according to the first embodiment;

FIG. 4B shows an example situation when the first embodiment dome switch is actuated;

FIG. 4C shows a different example situation when the first embodiment dome switch is actuated;

FIG. 5A shows a perspective view of a keycap assembly of a dome switch according to a second embodiment;

FIG. 5B shows a perspective view of the internal arrangement of the keycap (e.g., as shown in FIG. 5A) according to the second embodiment;

FIG. 6A shows a front view of an electrode arrangement of a dome switch according to the second embodiment;

FIG. 6B shows an example situation when the second embodiment dome switch is actuated; and

FIG. 6C shows a different example situation when the second embodiment dome switch is actuated.

### DETAILED DESCRIPTION OF EMBODIMENTS

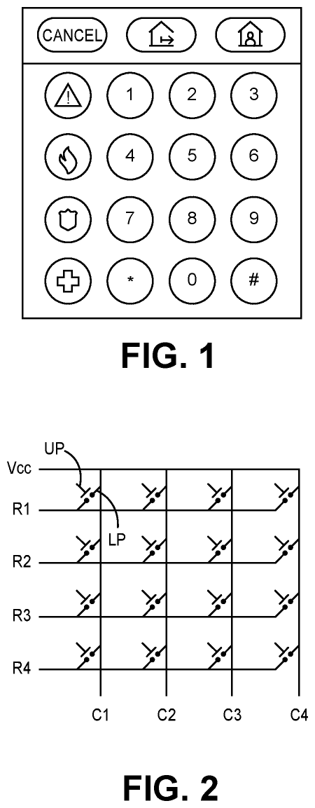

FIG. 1 shows the front view of an example keypad that forms an integral part on a control panel of a security system. As can be seen in the figure, the example keypad comprises an array of keycaps (also known as key covers or push buttons) each of which is associated with a particular numeric digit (e.g., dark grey buttons with “1”, “2” . . . “9”), symbol (e.g., dark grey buttons with “*”, “#”) or function (e.g., light grey buttons with “CANCEL” or other signs).

FIG. 2 shows part of a circuit diagram that is suitable for use in the example keypad shown in FIG. 1. As can be seen in the figure, 16 keypad switches (e.g., the lower 16 keycaps of the keypad shown in FIG. 1) are arranged into a 4 by 4 matrix (4 rows R1-4 and 4 columns C 1-4) sharing the same voltage supply (e.g., Vcc). Each switch comprises an upper portion UP (as indicated in the figure) which is or is connected to a keycap and a lower portion LP (as indicated in the figure) which comprises two electrodes both connected to the electrical circuit. At its default state (i.e. when no keycap is pressed), the electrical circuit between the two electrodes of the lower portion is open and thus no electrical signal is generated. However, when a keycap is pressed by a user, the upper portion of the corresponding key switch makes a temporary contact with the lower portion of the same switch such that the two circuit electrodes of the lower portion are electrically connected and an electrical signal in relation to the keycap is generated.

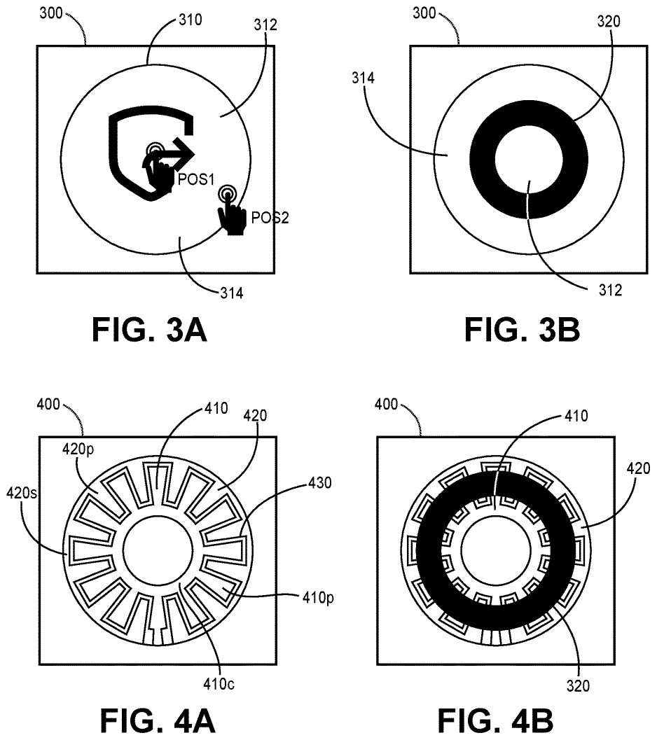

FIGS. 3A to 6B are related to embodiments of a dome switch. The dome switch may comprise a resiliently compressible keycap; at least one electrically conductive element enclosed by the resiliently compressible keycap; and a switch circuit located under the resiliently compressible keycap and the at least one electrically conductive element, the switch circuit comprising a first circuit board trace and a second circuit board trace, wherein the first circuit board trace and the second circuit board trace are electrically separated; wherein: the first circuit board trace comprises a central portion and a plurality of first projections extending from the central portion to form a non-convex shape; the second circuit board trace comprises a surrounding portion and a plurality of second projections extending from the surrounding portion to form a non-convex shape; wherein the second circuit board trace is arranged to enclose a majority part of the first circuit board trace and the first projections and the second projections are arranged to be positioned in an alternating manner; and wherein the dome switch is configured such that upon being depressed, the resiliently compressible keycap is operable to enable an electrical contact between the at least one electrically conductive element and at least part of the first circuit board trace and at least part of the second circuit board trace so as to temporarily complete the switch circuit.

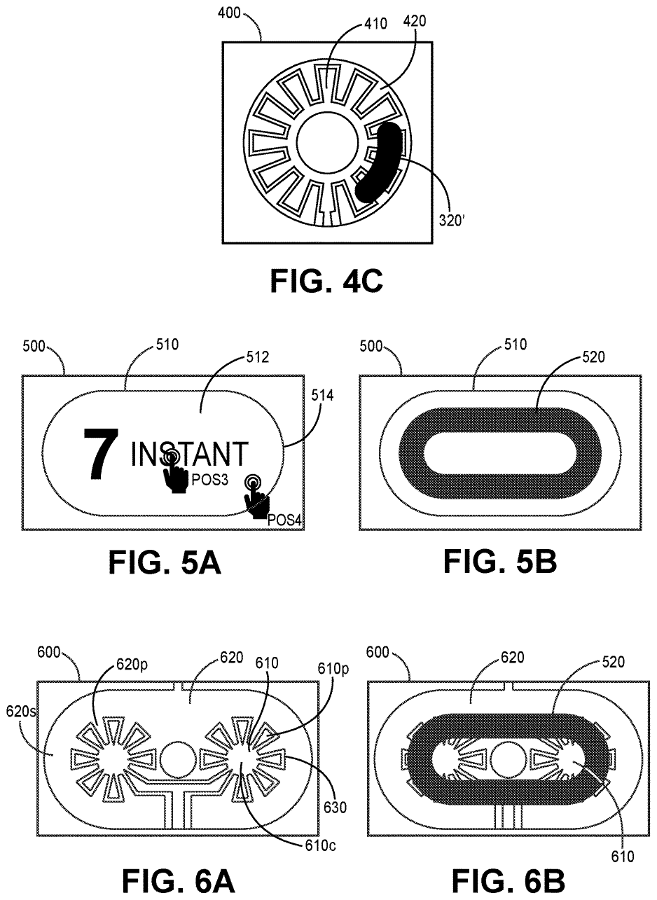

With reference to FIGS. 3A, 3B, and 4A, in a first embodiment, the dome switch may comprise two main portions, namely a keycap assembly 300 and an electrode arrangement 400. The keycap assembly 300 and the electrode arrangement 400 together form part of a switch circuit (e.g., as shown in FIG. 2). The keycap assembly 300 and the electrode arrangement 400 correspond respectively to the upper portion UP and lower portion LP of any switch of the circuit diagram shown in FIG. 2.

As shown in FIG. 3A and FIG. 3B, the keycap assembly 300 may comprise a resiliently compressible keycap 310 and an electrically conductive element 320. The resiliently compressible keycap 310 may be made from a flexible and resilient material, such as natural rubber, silicone or other elastic polymers. The keycap 310 may comprise a base 312 and a side wall 314 extending from the peripheral of the base 312 to the underling electrical circuit of the switch. The keycap 310 may comprise a flat or a non-flat top face. The outer contour of the base 312 may have different shapes, for example a square, a rectangle, an oval, or any other suitable shape. The keycap 310 may comprise a flat circular-shaped base 312. In a different embodiment, the keycap 310 may comprise a dome-like curved base 312. The keycap 310 with a flat base 312 may be preferable in cases where a graphic (e.g., symbol, letter or number) needs to be printed on the outer surface of the keycap 310, mainly because it may be easier to print on a flat surface than a curved surface.

As shown in FIG. 3B, the internal surface of the keycap 310 defines an empty cavity within which the electrically conductive element 320 is affixed. The electrically conductive element 320 may be made from any material that is electrically conductive. In an embodiment, the electrically conductive element 320 is preferably made from carbon (e.g., graphite) because of its light weight and low cost. In other embodiments, the electrically conductive element 320 may be made from a metal (e.g., gold) or a metal alloy (e.g., steel). The electrically conductive element 320 may be in different forms. In the embodiment shown in FIG. 3B, the electrically conductive element 320 is in the form of a circular-shaped ring structure. Such an electrically conductive ring 320 may be made from carbon. In a different embodiment, the electrically conductive element 320 may be in the form of a thin disk (e.g., a thin cylindrical disk). In an embodiment, the electrically conductive element 320 may be affixed to the internal surface of the circular base 312. In an embodiment, the electrically conductive element 320 may be affixed to the internal surface of the side wall 314. The electrically conductive element 320 may be affixed to the internal surface by means of an adhesive. In an embodiment, the electrically conductive element 320 may be embedded in the internal surface of the base 312. It is to be understood that in case a keycap with a different outer shape is used, the electrically conductive element is adapted accordingly.

As shown in FIG. 4A, the electrode arrangement 400 may be formed with a first circuit board trace 410 and a second circuit board trace 420 which are electrically separated. The two circuit board traces may act respectively as two electrodes of a switch circuit (e.g., as shown in FIG. 2). The first circuit board trace 410 may comprise a central portion 410c and a plurality of first projections 410p extending from the central portion 410c to form a non-convex shape. In an embodiment, the central portion 410c of the first circuit board trace 410 may further comprise an inner ring element and each of the plurality of first projections 410p may be separate from other projections and may extend outwardly from the inner ring element. The second circuit board trace 420 may comprise a surrounding portion 420s and a plurality of second projections 420p extending from the surrounding portion 420s to form a non-convex shape. In an embodiment, the surrounding portion 420s may further comprise an outer ring element and each of the plurality of second projections 420p may extend inwardly from the outer ring element. The second circuit board trace 420 may be arranged to enclose a majority part of the first circuit board trace 410, and the first projections 410p and the second projections 420p may be arranged to be positioned in an alternating manner, i.e. each first projection 410p is sandwiched by two second projections 420p and each first projection 410p is spatially separated from any adjacent second projection 420p by a gap 430.

The advantage of the electrode arrangement shown in FIG. 4A is that it enables reliable and consistent switch actuation even when the keycap 310 is pressed on the peripheral region of its base 312 (e.g., second position POS2 as indicated in FIG. 3A). When in use, the dome switch is actuated insofar as the first circuit board trace 410 and the second circuit board trace 420 are electrically connected. The electrical connection may be enabled by connecting electrically at least part (e.g., at least one first projection) of the first circuit board trace 410 with at least part (e.g., at least one second projection) of the second circuit board trace 420. The actuation sensitivity of the dome switch may be dependent on the number of the first projections 410p and second projections 420p. The actuation sensitivity of the dome switch may be dependent on the structure of the electrically conductive element 320. Generally, the larger the number of the first projections 410p and second projections 420p is, the higher the actuation sensitivity will be. Also, the larger the overlapping area between the electrically conductive element 320 and the electrode arrangement 400 is, the higher the actuation sensitivity will be.

The first circuit board trace 410 may be arranged to form at least four first projections 410p, at least six first projections 410p, at least eight first projections 410p, at least ten first projections 410p, or at least twelve first projections 410p. Since the first projections 410p and the second projections 420p are positioned in an alternating manner, the total number of the first projections 410p is the same as that of the second projections 420p. The shape of the first projections 410p and the shape of the second projections 420p may be flexibly chosen. Preferably the two shapes are complementary to each other. In an embodiment, the first projections 410p and the second projections 420p may both have a trapezoid shape and may be arranged in an interlocking manner, as shown in FIG. 4A.

Referring back to FIG. 3A and FIG. 4A, the dome switch may be arranged such that the outer contour of the electrode arrangement 400 is fully enclosable by the side wall 314 of the keycap 310. Additionally or optionally, the dome switch may be arranged such that the electrically conductive element 320 is fully within the boundary of the electrode arrangement 400. Such an arrangement may allow the electrically conductive element 320 to be in contact with substantial portion or even all of first projections 410p and second projections 420p (as shown in FIG. 4B). It will be appreciated that the outer contours of the keycap 310 and the electrode arrangement 400 are not limited to the circular shape. The shapes of the outer contours of the keycap 310 and the electrode arrangement 400 may be flexibly chosen depending on application needs. In some embodiments, the outer contours of the keycap 310 and optionally the electrode arrangement 400 may have a polygonal shape (e.g., pentagons, hexagons, heptagon, or octagon).

As described above, when a pressing force is applied to the keycap 310, the keycap 310 is collapsed which results in the electrically conductive element 320 being in physical contact with at least part of the underneath electrode arrangement 400. With reference to FIGS. 3A and 4B, in the case where the pressing force is applied at the first position POS1 which is in the central region of the keycap 310 and where the pressing force is along a direction substantially perpendicular to the flat top face of the keycap 310 and substantially in the centre of the keycap 310 (this direction is defined as the on-axis direction), the keycap 310 is collapsed in a substantially symmetrical manner resulting in the entire electrically conductive element 320 sitting on the electrode arrangement 400 and in-between the central portion 410c of the first circuit board trace 410 and the surrounding portion 420s of the second circuit board trace 420. In such a case, the electrically conductive element 320 is in physical contact with all of the first projections 410p and the second projections 420p. The physical contact between the electrically conductive element 320 and the first projections 410p and second projections 420p enables electrical connection of the first circuit board trace 410 and the second circuit board trace 420 and thus completion of the electrical circuit of the dome switch. The completion of the electrical circuit of the dome switch in turn leads to generation of an electrical signal associated with the switch and thus registration of the keystroke. Subsequently, upon removing of the pressing force, the collapsed keycap 310 self-recovers its default form resulting in the disconnection of the first circuit board trace 410 and the second circuit board trace 420, and thus opening of the electrical circuit of the dome switch.

Note that FIG. 4B illustrates an ideal use case. In real-life scenarios, the pressing force may often be applied at a non-central position on the keycap 310 and the pressing force may follow an off-axis direction. Here, the off-axis direction is any direction that does not overlap with the on-axis direction as defined above. By way of example, FIG. 4C illustrates a situation where a pressing force is applied at the second position POS2 which is in the peripheral region of the keycap 310 (as shown in FIG. 3A) and the pressing force follows an off-axis direction. In such a case, the keycap 310 is collapsed in an asymmetric manner which results in only part 320′of the electrically conductive element 320 being in physical contact with part of the electrode arrangement 400. As shown in FIG. 4C, in spite of the keycap 310 being pressed in a peripheral region and along an off-axis direction, part 320′ of the electrically conductive element 320 stills makes contact with three first projections 410p and three second projections 420p and as such the switch can still be actuated. The electrical circuit of the switch is completed even if only one first projection 410p is electrically connected to one second projection 420p.

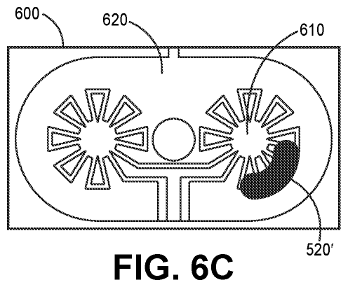

With reference to FIGS. 5A, 5B, and 6A, in a second embodiment, the dome switch may comprise a keycap assembly 500 and an electrode arrangement 600. As shown in FIG. 5A and FIG. 5B, the keycap assembly 500 may comprise a resiliently compressible keycap 510 and an electrically conductive element 520, both having a long oval-shaped outer contour. Here, the electrically conductive element 520 comprises a long oval-shaped ring structure. The keycap 510 comprises a flat long oval-shaped base 512 and a side wall 514 extending from the peripheral of the long oval-shaped base to the underneath electrode arrangement 600. The internal surface of the keycap 510 defines an empty cavity within which the electrically conductive element 520 is affixed. Other than the difference in shape, the keycap assembly 500 of the second embodiment has similar properties and works in a similar manner as the keycap assembly 300 of the first embodiment.

As shown in FIG. 6A, the electrode arrangement 600 is formed with a first circuit board trace 610 and a second circuit board trace 620 which are electrically separated. The two circuit board traces act respectively as two electrodes of a switch circuit (e.g., as shown in FIG. 2). The first circuit board trace 610 may comprise at least two base portions, each comprising a central portion 610c and a plurality of first projections 610p extending from the central portion 610c to form a non-convex shape. Thus, the first board trace 610 of the second embodiment can be regarded as being formed by two electrically connected first board traces 410 of the first embodiment. The second circuit board trace 620 comprises a surrounding portion 620s and a plurality of second projections 620p extending from the surrounding portion 620s to form a non-convex shape. Similarly, the second circuit board trace 620 of the second embodiment can be regarded as being formed by two electrically connected second board traces 610 of the first embodiment. The second circuit board trace 620 is arranged to enclose a majority part of the first circuit board trace 610 and the first projections 610p and the second projections 620p are arranged to be positioned in an alternating manner, i.e. each first projection 610p is sandwiched by two second projections 620p and each first projection 610p is spatially separated from any adjacent second projection 620p by a gap 630.

With reference to FIGS. 5A and 6B, in the case where the pressing force is applied at the third position POS3 which is in the central region of the keycap 510 and where the pressing force is along a direction substantially perpendicular to its flat top face (this direction is defined as the on-axis direction), the keycap 510 is collapsed in a substantially symmetrical manner resulting in the entire electrically conductive element 520 sitting on the electrode arrangement 600. In this case, the electrically conductive element 520 may be in physical contact with most but not all of the first projections 410p and the second projections 420p. Being unable to make physical contact with all of the first projections 410p and the second projections 420p may be mainly due to the size of the keycap 510 and the ring structure of the electrically conductive element 520. Although it may not be necessary, improvement can nevertheless be achieved by replacing the ring-type electrically conductive element 520 with for example a disk-type electrically conductive element 520. The disk-type electrically conductive element 520 may have a larger overlapping area with the electrode arrangement 600 and may thus lead to a higher sensitivity. However, the disk-type electrically conductive element 520 may be heavier and more expensive than the ring-type counterpart.

FIG. 6C illustrates a situation where a pressing force is applied at the fourth position POS4 which is in the peripheral region of the keycap 510 (as shown in FIG. 5A) and which follows an off-axis direction. In such a case, the keycap 510 is collapsed in an asymmetric manner which results in only part 520′ of the electrically conductive element 520 being in physical contact with part of the electrode arrangement 600. As shown in FIG. 6C, in spite of the keycap 510 being pressed in a peripheral region and along an off-axis direction, part 520′ of the electrically conductive element 520 stills makes contact with three first projections 410p and two second projections 420p and as such the switch can still be actuated. Similar to the first embodiment, the actuation sensitivity of the dome switch may be dependent on the number of the first projections 610p and second projections 620p as well as the structure of the electrically conductive element 520.

Other configurations of the dome switch are possible. For example, in an embodiment, the keycap assembly 500 may comprise a resiliently compressible keycap 510 and two spatially separate electrically conductive elements 520. Each of the two electrically conductive elements 520 may be affixed above one base portion of the first circuit board trace 610 and arranged to be contactable with at least part of the first circuit board trace 610 and at least part of the second circuit board trace 620 when the keycap 510 is pressed. In an embodiment, each of the two electrically conductive elements 520 may be in the form of a circular-shaped ring structure, e.g., as shown in FIG. 3B. In a different embodiment, each of the two electrically conductive elements 520 may be in the form of a circular-shaped thin disk. Whereas, in another different embodiment, one of the two electrically conductive elements 520 may be in the form of a circular-shaped ring structure and the other one may be in the form of a circular-shaped thin disk. It will be appreciated that other different numbers (e.g., more than two), and/or shapes (e.g., polygonal shapes), and/or forms of the electrically conductive elements 520 may also be applicable for the embodiments described above.

Note that, the above description is for illustration only and other embodiments and variations may be envisaged without departing from the scope of the invention.

1. A dome switch, comprising a resiliently compressible keycap;
at least one electrically conductive element enclosed by the resiliently compressible keycap; and
a switch circuit located under the resiliently compressible keycap and the electrically conductive element, the switch circuit comprising a first circuit board trace and a second circuit board trace, wherein the first circuit board trace and the second circuit board trace are electrically separated; wherein:
the first circuit board trace comprises a central portion and a plurality of first projections extending from the central portion to form a non-convex shape;
the second circuit board trace comprises a surrounding portion and a plurality of second projections extending from the surrounding portion to form a non-convex shape; wherein the second circuit board trace is arranged to enclose a majority part of the first circuit board trace and the first projections and the second projections are arranged to be positioned in an alternating manner; and
wherein the dome switch is configured such that upon being depressed, the resiliently compressible keycap is operable to enable an electrical contact between the at least one electrically conductive element and at least part of the first circuit board trace and at least part of the second circuit board trace so as to temporarily complete the switch circuit.

2. The dome switch as claimed in claim 1, wherein the central portion of the first circuit board trace comprises an inner ring element and each of the plurality of first projections is separate from others and extends outwardly from the inner ring element, and wherein the surrounding portion comprises an outer ring element and each of the plurality of second projections extends inwardly from the outer ring element and is arranged to be placed in a gap formed between any two immediately adjacent first projections of the plurality of first projections of the first circuit board trace.

3. The dome switch as claimed in claim 1, wherein first circuit board trace comprises at least two base portions, each base portion comprising a central portion and a plurality of first projections extending from the central portion to form a non-convex shape.

4. The dome switch as claimed in claim 1, being arranged such that the number of the first projections equals to the number of the second projections.

5. The dome switch as claimed in claim 1, wherein the first projections of the first circuit board trace and the second projections of the second circuit board trace are arranged to have complementary shapes.

6. The dome switch as claimed in claim 5, wherein the first projections and the second projections both have a trapezoid shape.

7. The dome switch as claimed in claim 1, wherein the resiliently compressible keycap comprises a base and a side wall extending from the peripheral of the base to the underling switch circuit.

8. The dome switch as claimed in claim 7, wherein the base of the resiliently compressible keycap comprises a flat top face on which a pressing force is applicable.

9. The dome switch as claimed in claim 7, wherein the base of the resiliently compressible keycap comprises a curved top face on which a pressing force is applicable.

10. The dome switch as claimed in claim 7, wherein the base and the side wall of the keycap are arranged to provide an internal surface defining an cavity for enclosing the at least one electrically conductive element.

11. The dome switch as claimed in claim 10, wherein the keycap is arranged such that the at least one electrically conductive element is affixed to the internal surface of the base and/or the side wall of the keycap.

12. The dome switch as claimed in claim 1, wherein each of the at least one electrically conductive element is made from carbon or a metal.

13. The dome switch as claimed in claim 1, wherein each of the at least one electrically conductive element is in the form of a ring structure.

14. The dome switch as claimed in claim 1, wherein each of the at least one electrically conductive element is in the form of a disk structure.

15. The dome switch as claimed in claim 10, being arranged such that the electrode arrangement is fully enclosable by the side wall of the keycap and the at least one electrically conductive element is within a boundary of the electrode arrangement.

16. A switch comprising
a resiliently compressible keycap;
at least one electrically conductive element enclosed by the resiliently compressible keycap; and
a switch circuit located under the resiliently compressible keycap and the electrically conductive element, the switch circuit comprising a first circuit board trace and a second circuit board trace, wherein the first circuit board trace and the second circuit board trace are electrically separated; wherein:
the first circuit board trace comprises a central portion and a plurality of first projections extending from the central portion to form a non-convex shape; and
the second circuit board trace comprises a surrounding portion and a plurality of second projections extending from the surrounding portion to form a non-convex shape; wherein the second circuit board trace is arranged to enclose a majority part of the first circuit board trace and the first projections and the second projections are arranged to be positioned in an alternating manner.

17. The switch as claimed in claim 16, wherein the switch is configured such that upon being depressed, the resiliently compressible keycap is operable to enable an electrical contact between the at least one electrically conductive element and at least part of the first circuit board trace and at least part of the second circuit board trace so as to temporarily complete the switch circuit.

18. The switch as claimed in claim 16, wherein the central portion of the first circuit board trace comprises an inner ring element and each of the plurality of first projections is separate from others and extends outwardly from the inner ring element, and
wherein the surrounding portion comprises an outer ring element and each of the plurality of second projections extends inwardly from the outer ring element and is arranged to be placed in a gap formed between any two immediately adjacent first projections of the plurality of first projections of the first circuit board trace.

19. The switch as claimed in claim 16, wherein first circuit board trace comprises at least two base portions, each base portion comprising a central portion and a plurality of first projections extending from the central portion to form a non-convex shape.

20. The switch as claimed in claim 16, being arranged such that the number of the first projections equals to the number of the second projections.
